(19) United States
(12) Patent Application Publication
(10) Pub. No.: US 2008/0308300 A1
(43) Pub. Date: Dec. 18, 2008

(54) METHOD OF MANUFACTURING ELECTRICALLY CONDUCTIVE STRIPS

(76) Inventors: Mark A. Conti, Waterbury, CT (US); Raymond E. Stupak, Litchfield, CT (US); Ronald D. Gross, Storrs, CT (US)

Correspondence Address: CANTOR COLBURN, LLP, 20 Church Street, 22nd Floor, Hartford, CT, 06103, US

(21) Appl. No.: 12/139,892

(22) Filed: Jun. 16, 2008

Related U.S. Application Data
(60) Provisional application No. 60/944,557, filed on Jun. 18, 2007.

(51) Int. Cl. H05K 1/09; B05D 5/12

(52) U.S. Cl. 174/250; 427/97.6

(57) ABSTRACT

A silver layer (24) is sandwiched between a tin layer (20) and a tin top coat (28) on an electrically-conductive substrate (14) which may comprise copper. The substrate having the three discrete metal layers thereon is heated to a temperature of at least about 220° C., preferably from about 220° C. to about 410° C., to melt the three layers. The melted layers are cooled to cause them to re-solidify as a tin-silver alloy layer (32) in which the silver is fully dispersed. A coated electrically conductive substrate (214) made as described above may be used as an electrical contact material.

### CROSS-REFERENCE TO RELATED APPLICATION

This application claims the benefit of priority of provisional patent application Ser. No. 60/944,557, entitled “METHOD OF MANUFACTURING ELECTRICALLY CONDUCTIVE STRIPS”, filed on Jun. 18, 2007.

### BACKGROUND OF THE INVENTION

1. Field of the Invention

The present invention concerns a method for manufacturing electrically conductive strips comprised of an electrically conductive base material coated with a tin-silver alloy. Such coated materials often have the form of coated metal strips or wires and frequently find utility as electrical or electronic connectors, terminals and contacts, for example, in automotive applications.

2. Related Art

In the manufacture of electronic and electrical components and assemblies, tin-lead alloys were commonly applied to the surfaces of electrically conductive components to provide readily solderable surfaces. Such components, e.g., leadframes, strips and wire, are generally comprised of copper or various copper alloys, although other electrically conductive materials are sometimes used. The lead contained in the tin-lead alloy coatings is an environmental and medical hazard and therefore a tin-silver alloy is preferred in order to eliminate the lead hazard without sacrificing the favorable characteristics obtainable with tin-lead alloys. These characteristics include good solderability and a reduced propensity for tin-whisker growth. Tin-silver alloys have the further advantage of minimizing the propensity for the dissolution of silver-coated component surfaces by the solder.

The art has, however, encountered some difficulty in substituting tin-silver alloys for tin-lead alloys. For example, electroplating a tin-silver alloy having a composition with optimal tin to silver ratios to provide readily solderable surfaces for electronic applications, is problematic. Silver and tin have significantly different reduction potentials in an electroplating solution. As a consequence, the more noble component (silver) deposits too rapidly at the more negative potentials required for deposition of the less noble component (tin); adequate control over the optimum deposit condition is, therefore, practically unattainable. See the article by N. Kubota and E. Sato, Electrochim. Acta 30, 305, (1985).

U.S. Pat. No. 6,207,035, issued Mar. 27, 2001 to U. Adler et al. and entitled “Method For Manufacturing A Metallic Composite Strip” (“the '035 patent”) discloses a method for manufacturing a metal composite strip for production of electrical contact components. Tin or a tin alloy film is deposited onto an electrically conductive base material, preferably, a copper or copper alloy base material. A film of silver is then deposited over the tin or tin alloy. The Patentee discloses that both the tin film and silver film may be deposited by electroplating or the tin film may be applied as molten tin and the silver film by electroplating. If the tin film is deposited in the molten state, the silver film may be deposited by cathodic sputtering. Diffusion of the components during the coating is said to result in a homogeneous film of a tin-silver alloy, and the diffusion may be assisted by optional heat treatment of the coated composite strip. See column 1, lines 37-50. At column 2, lines 39-44, heat treatment in the form of a diffusion anneal is stated to ensure reliable equalization of any concentration differences that may still exist in the film structure of the applied coating. Such heat treatment of the composite strip is preferably accomplished using a pass-through process, at a temperature between 140° C. and 180° C. (See column 2, lines 43-45.) Heat treatment at the same temperature range of 140° C. to 180° C. may also be carried out on the tinned strip, i.e., prior to application of the silver, as noted at column 2, lines 49-53. The recommended temperature range of between 140° C. to 180° C. for the diffusion heat treatment lies well below the melting point of both tin (231.9° C.) and silver (960.5° C.) and therefore relies upon thermal interdiffusion, a time-consuming process. At the heat treatment temperatures specified in the '035 patent, complete homogenization by thermal interdiffusion of the layers of tin and silver of specified thickness is believed to require at least a substantial fraction of an hour, and perhaps longer, to attain.

U.S. Pat. No. 6,924,044, issued Aug. 2, 2005 to R. W. Strobel and entitled “Tin-Silver Coatings” (“the '044 patent”) discloses coatings for electrical or electronic connectors such as contacts or terminals used in automotive applications (see the Abstract and column 1, lines 11-15.) The '044 patent discloses applying a tin-silver coating to an electrically conductive substrate such as copper, a copper alloy, a carbon steel material, or an aluminum alloy (column 2, lines 53-65). In addition to the tin and silver, the coating may contain up to about 5.0 weight percent of at least one hardening element selected from bismuth, silicon, copper, magnesium, iron, nickel, manganese, zinc, antimony and mixtures thereof (column 3, lines 14-28). The Patentee states that the tin-silver coatings may be applied to the electrically conductive substrate material “using any suitable technique known in the art.” (column 3, lines 29-31) but expresses a preference for applying the tin-silver coating utilizing a non-electroplating technique, for example, by immersing the electrically conductive substrate material into a tin-silver bath maintained at a temperature of at least 500° F., preferably at a temperature in the range of from 500° F. to about 900° F. (See column 3, lines 33-42.)

U.S. Pat. No. 7,147,933, issued Dec. 12, 2006 to Richard W. Strobel and entitled “Tin-Silver Coating” (“the '933 patent”) relates to improved coatings for electrical or electronic connectors. The tin-silver coating, which may be applied to any suitable electrically conductive material such as copper, a copper alloy, a carbon steel material or an aluminum alloy, is stated to preferably consist of more than 1.0 weight percent to about 20 weight percent silver, with the balance essentially tin. Preferred narrower ranges within the 1.0 to 20 weight percent silver are also disclosed. (See column 1, line 64 to column 2, line 11.) As disclosed starting at column 2, line 12 et seq., the binary tin-silver coatings may also contain an effective amount up to about 5.0 weight percent of at least one hardening element elected from bismuth, silicon, copper, magnesium, iron, nickel, manganese, zinc, antimony and mixtures thereof. Column 3, lines 1-15, disclose tin-silver coatings of various compositions and notes that such coatings have a melting point greater than 225° C.

### SUMMARY OF THE INVENTION

Generally, in accordance with the present invention there is provided a method of manufacturing an electrically conductive substrate coated with a tin-silver alloy, for example, an electrical contact material comprising a tin-silver alloy coating on an electrically conductive substrate. The tin-silver alloy may have a silver concentration gradient, preferably with the silver concentration increasing towards the outer surface of the tin-silver alloy.

Specifically, in accordance with the present invention there is provided a method of manufacturing an electrically conductive substrate, e.g., a copper substrate, having a tin-silver alloy coated on at least one surface of the substrate with the tin-silver alloy having an outer surface. The method comprises the following steps. There is applied to the surface of the substrate a surface coating comprising a tin prime coat, an intermediate silver coat over the tin prime coat, and a tin top coat over the intermediate silver coat. The coated substrate is heated to an elevated temperature of at least about 220° C., e.g., from about 220° C. to about 410° C., which temperature is sufficiently high to melt the entirety of the coating, and maintaining the coated substrate at the elevated temperature for at least a time sufficient to melt the entire coating and fully disperse the silver therein (“the melt duration”). Thereafter the coating is cooled to re-solidify it and thereby provide a solid, reflowed tin-silver alloy coating on the electrically conductive substrate. For example, the tin-silver alloy may comprise from about 5 to about 40 weight percent silver.

In accordance with another aspect of the present invention, there is provided a method of manufacturing electrical contact material comprising the following steps. There is applied to at least one surface of an electrically conductive substrate, e.g., a copper substrate, a reflowed tin-silver alloy coating having an outer surface and comprising from about 5 to about 40 weight percent silver. The method comprises applying to the surface of the substrate a tin prime coat; an intermediate silver coat applied over the tin prime coat; and a tin top coat applied over the silver intermediate coat. The thus-coated substrate is then heated to an elevated temperature of at least about 220° C., which temperature is sufficiently high to melt the applied tin and silver layers, and maintaining the coated substrate at the elevated temperature for at least a time sufficient to melt all the tin and silver layers and fully disperse the silver therein (the “melt duration”). Thereafter, the coated substrate is cooled, e.g., by forced air applied to the outer surface of the tin-silver coating to re-solidify the melted tin and silver to thereby provide a reflowed tin-silver alloy on the substrate.

Other aspects of the present invention provide one or more of the following features, alone or in combination: the intermediate silver coat is thinner than either of the tin prime coat and the tin top coat; the intermediate silver coat is thin enough whereby the entirety of the intermediate silver coat will melt and disperse into the tin coats when the coating is subjected to a temperature of from about 220° C. to about 410° C. for a melt duration of from about 0.05 to about 5 seconds; and the intermediate silver coat is from about 4 to about 12 microinches in thickness.

In one aspect of the present invention, the above method further includes applying a metal underplate layer to the surface before applying the tin prime coat of the coating; the metal underplate layer may be selected from the group consisting of one or more of copper and nickel, e.g., nickel.

Still another aspect of the invention provides that the tin and silver coats and, optionally, the underplate layer, are all applied to the electrically conductive substrate by electrolytic plating from separate tin and silver and optional underplate plating baths.

Other aspects of the present invention provide one or more of the following: the melt duration is from about 0.05 to about 5 seconds, e.g., about 0.1 to about 3 seconds; and applying to the coating additional alternating tin and silver coats with each silver coat sandwiched between two tin coats.

Another aspect of the present invention provides a coated electrically conductive substrate having thereon a tin-silver alloy coating having an outer surface. The silver is fully dispersed within the tin-silver alloy coating and there is a silver concentration gradient extending through the thickness of the coating from the electrically conductive substrate to the outer surface of the tin-silver alloy coating. The coated substrate may optionally be configured as an electrical contact device.

The coated electrically conductive substrate may be made by any of the methods described above.

A related aspect of the present invention provides that the silver concentration gradient increases at least adjacent the outer surface of the tin-silver alloy coating in the direction from the substrate to the outer surface of the tin-silver alloy coating.

The term “fully dispersed” as used herein and in the claims means that the original discrete all-silver layer is not left in the reflowed tin-silver alloy, but that silver is dispersed through the tin-silver alloy, even though concentration gradients of tin and silver may be present in the alloy.

The terms “tin”, “silver”, “copper” “nickel” and any reference to other metals, unless otherwise specified or required by the context, mean and include the elemental metals and suitable, for the intended purpose, alloys of the metals, especially those of the type suitable for electrical and electronic connectors, terminals and contacts, more especially for such of the foregoing as find utility in automotive applications.

### BRIEF DESCRIPTION OF THE DRAWINGS

FIG. 1 is a schematic view in elevation of a manufacturing line usable to produce an electrically-conductive base material coated with a tin-silver alloy in accordance with one embodiment of the present invention;

FIG. 2A is a schematic partial elevation view, enlarged relative to FIG. 1, of a coated electrically conductive strip at an intermediate stage of production on the manufacturing line of FIG. 1;

FIG. 2A-1 is a view corresponding to that of FIG. 2A but of an alternate embodiment of the invention;

FIG. 2B is a view corresponding to that of FIG. 2A, but showing the strip after processing is complete;

FIG. 3 is a schematic plan view, enlarged relative to FIG. 1, of an electrically conductive strip usable as an electrically conductive substrate to be coated in the manufacturing line of FIG. 1;

FIG. 4 is a graph plotting temperature equilibrium data for tin-silver alloys; and

FIG. 5 is a schematic cross-sectional view of a coated electrically conductive substrate in accordance with one embodiment of the present invention with numbered locations thereon.

### DETAILED DESCRIPTION OF EMBODIMENTS OF THE INVENTION

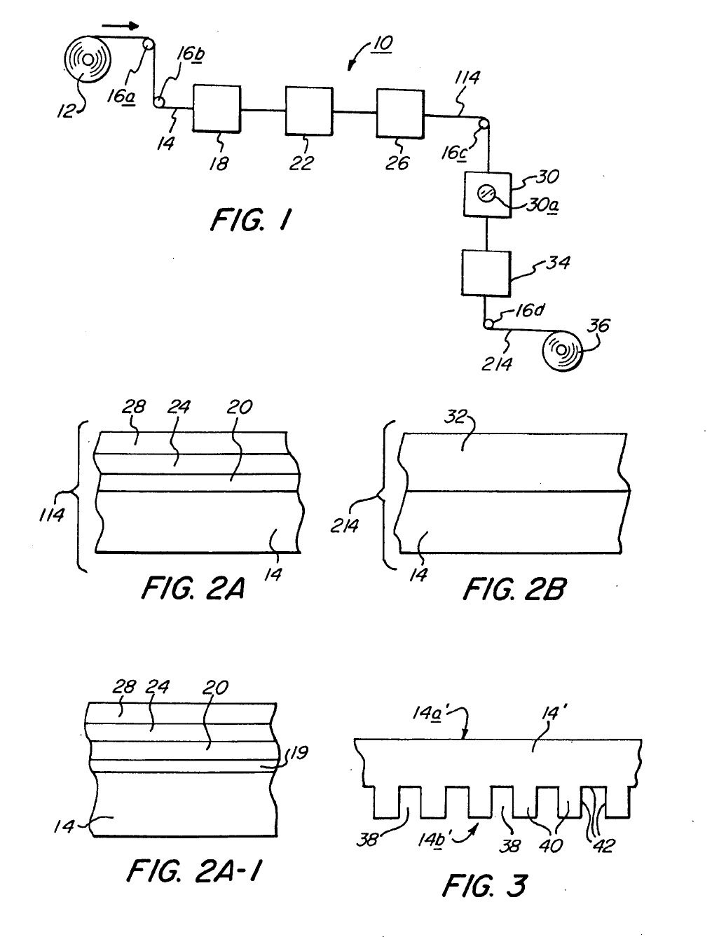

Referring now to FIG. 1, a manufacturing line 10 includes a feed reel 12 which supplies a continuous strip of electrically conductive substrate 14. Electrically conductive substrate 14 may be any suitable electrically conductive material such as copper, steel, etc. A pair of guide rollers 16a, 16b directs strip 14 through a tin deposition zone 18 which may comprise any suitable apparatus for depositing a first tin prime layer upon electrically conductive substrate 14. Thus, tin deposition zone 18 may comprise an electrolytic ion reduction process, an electrolysis process, a catalytic reduction process or a chemical replacement process. As shown in FIG. 2A, a tin plating layer 20 is deposited upon electrically conductive substrate 14 in zone 18. Electrically conductive substrate 14 with layer 20 thereon is then passed into a silver deposition zone 22 in which a controlled thickness of silver, preferably applied via electrolytic ion reduction, is deposited as a silver layer 24 which, as shown in FIG. 2A, overlies prime coat tin layer 20. Electrically conductive substrate 14, with tin and silver layers 20, 24 thereon, is then passed into and through a second tin deposition zone 26 in which a tin top coat layer 28 is deposited over the silver layer 24, as shown in FIG. 2A. Electrically conductive substrate 14 with the three layers 20, 24 and 28 deposited thereon emerges from second tin deposition zone 26 as multi-layer-coated electrically conductive substrate 114 (see FIGS. 1 and 2A).

In order to enhance control of the thickness of the individual layers of tin and silver, it is preferred that an electrolytic ion reduction process be used at least for the silver layer and the tin top coat layer. Most preferably, electrolytic ion reduction is utilized to deposit all three or more layers as well as the underplate layer in order to provide the best possible control of thickness of the individual deposited metal layers. Suitable alloying or modifying ingredients may be added to the three separate tin, silver and underplate plating baths, as desired. The total thickness of the tin layers as compared to the total thickness of the silver layer or layers will, of course, determine the overall tin-to-silver ratio of the resulting tin-silver alloy.

Generally, the tin layers deposited onto the electrically conductive substrate may comprise any suitable all-tin or tin alloy, such as that of the above mentioned '933 patent, which contains an effective amount of from about 0.1 to about 5 weight percent of hardening agents selected from the group consisting of one or more of bismuth, silicon, copper, magnesium, iron, nickel, manganese, zinc and antimony. One or more other alloying ingredients or modifying ingredients may comprise one or more of conventional brighteners, brightener/wetting agents and grain refiners. Similarly, the silver may comprise any suitable all silver or silver alloy, and may comprise one or more suitable modifying agents. The unmelted composite layers of tin and silver may be of any suitable thickness. When coated on the electrically conductive substrate, the composite layer may be from about 40 to about 120 microinches or more in thickness, with each layer being of a thickness to yield the desired ratio of tin to silver in the finished alloy coating. Of course, any suitable thicknesses of the individual tin and silver metal deposits may be utilized.

It has been found that melting and dispersion of tin and silver into the eventual tin-silver alloy is facilitated by sandwiching each of the silver coat or coats between two coats of tin. This facilitates the melting and dispersing of the thin coat or coats of silver, for example, thin silver coats from about 4 to about 120 microinches in thickness, at temperatures significantly below the melting point of pure silver. The use of such thin silver coats applies as well to producing thicker tin-silver alloy coatings, e.g., greater than about 120 microinches in thickness. To obtain such thicker tin-silver alloy coatings, a plurality of thin silver coats sandwiched between tin coats may be employed. It is therefore within the purview of the invention to add additional alternating tin and silver layers to the coating. The “sandwich” construction of a silver coat between two coats of tin also ensures that a tin coat will be directly deposited onto the substrate or the underplate. This provides better wetting and uniformity of coating of the tin-silver alloy onto the substrate.

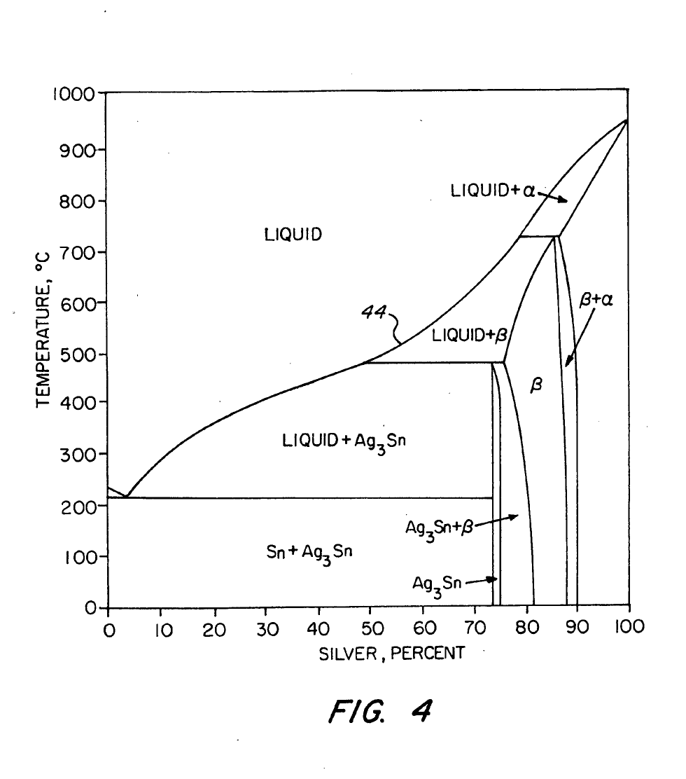

Multi-layer coated electrically conductive substrate 114 is then passed over a guide roller 16c to guide it vertically through a heating zone 30 in which multi-layer coated electrically conductive substrate 114 is heated sufficiently to melt the three deposited layers 20, 24 and 28. Vertical heating zone 30 has a visual observation port 32a through which the point at which the coatings 20, 24, 28 melt may be observed. Upon melting, the dull matte finish becomes shiny and wet-looking. Such observation helps to properly set the temperature within heating zone 30 and the line speed to maintain proper melt duration. Infrared temperature sensing devices (not shown) may be used to monitor temperatures within heating zone 30. The heat in heating zone 30 could be supplied by any suitable means including radiation heating, convection heating or induction heating or any other suitable heat source. Within heating zone 30 the deposited metal layers 20, 24 and 28 are heated to a temperature of at least about 220° C., e.g., to about 410° C. or potentially as high as 800° C. or even higher in extreme cases. The development of more efficient heating methods, or the requirement of a high silver content of the tin-silver alloy regardless of cost, might call for the tin-silver alloy to have a silver content of up to about 70 weight percent or more, with a concomitant increase in the melting point, as shown by the graph of FIG. 4. In any case, the heating is carried out at a temperature which is high enough to ensure rapid melting of all three layers 20, 24 and 28 of the coating. The tin-silver alloy is heated at a temperature which will maintain the alloy at or above, preferably at least 5° C. above, e.g., 10° C. or 15° C. or above, the melting point temperature of the specific tin-silver alloy used. For example, the melt temperature may be from about 220° C. to about 410° C. The coated electrically conductive substrate is held within that temperature range for a time sufficient to ensure that the molten tin and silver mix to form upon cooling and resolidification a dispersed tin-silver alloy. This period of time for which the coated electrically conductive substrate is held within the melt temperature range (the “melt duration”) may be very short, e.g., from about 0.05 to about 5 seconds, for example, from about 0.1 to about 3 seconds. The melt duration and the melt temperature will depend on the composition of the tin and silver layers, e.g., the specific tin alloys and silver alloys used, the amount of optional additives in such metals or alloys, and the thickness of the tin-silver coating. The linear speed of the manufacturing line and the size of the heating (reflow) oven may impose a melt duration which is somewhat longer than the minimum melt duration required for producing a fully dispersed tin-silver alloy, but that does not cause any difficulties. Upon exiting from heating zone 30, the tin-silver alloy coated onto electrically conductive substrate 214 is cooled or allowed to cool until tin-silver alloy layer 32 solidifies. This is accomplished by passing alloy-coated electrically conductive substrate 214 through a cooling zone 34 which may simply consist of an area for ambient air-cooling or it may comprise any suitable quenching step such as an air blower or water spray or bath. The alloy-coated electrically conductive substrate 214, with the alloy 32 in solid form, is then passed over guide roller 16d to take-up reel 36. When take-up reel 36 is filled, it may be placed in storage or sent for further processing or use.

Upon re-solidification of the composite coating, a fully dispersed tin-silver alloy layer 32 (FIG. 2B) is formed on electrically conductive substrate 14 to provide an alloy-coated electrically conductive substrate 214. This result is assured by keeping the melting temperature above the liquid-solid temperature line (44 in FIG. 4) for the specific tin-silver alloys used. A gradient of concentration of silver dispersed in the tin may be promoted by differential cooling of the molten coating; it has been found that silver tends to migrate to those areas of the coating which are first to solidify. This aspect of the invention is discussed in more detail below. The requisite temperature required in a given case is further discussed below with respect to the phase diagram of FIG. 4.

Prior to the application of any tin or silver (or nickel, copper, etc.) layers thereto, electrically conductive substrate 14 may have any suitable shape such as a ribbon shape of generally uniform thickness and width along its entire length, or it may be cut or otherwise formed to have any suitable required shape such as the crenellated shape shown in plan view in FIG. 3 for electrically conductive substrate 14′. Electrically conductive substrate 14′ is of elongate, ribbon-like configuration but has been cut to provide along one edge thereof a series of transverse slots 38 separated by laterally protruding tabs 40. Accordingly, in this embodiment, one lateral edge 14a′ of electrically conductive substrate 14′ is smooth whereas the opposite lateral edge 14b′ is crenellated by cutting transverse slots 38 therein. By carrying out the cutting or shaping of electrically conductive substrate 14′ prior to applying the tin and silver layers, cut edges 42, i.e., the edges resulting from cutting out the slots 38, may be coated with the tin-silver alloy during the manufacturing processes. If the cutting of transverse slots 38 were done after application of the tin-silver alloy, cut edges 42 would lack the tin-silver alloy coating and result in exposed electrically conductive substrate 14′ along cut edges 42.

Prior to deposition of the tin prime layer 20, the invention provides for the optional deposition of a metal underplate layer 19 (FIG. 2A-1) of copper, nickel or any other metal or alloy suitable for the purpose. The underplate layer 19 is followed by the tin prime layer 20, then the silver layer 24 and finally the tin top layer 28. FIG. 2A-1 illustrates this embodiment, showing the metal underplate layer 19. Generally, the underplate layer 19, when utilized, is deposited in a thickness of from about 15 to about 100 microinches. Whether or not a metal underplate layer 19 is utilized, the two tin layers 20, 28 (FIGS. 2A and 2A-1) may cumulate to from about 75 to about 95 percent of the total thickness of the deposited layers 20, 24 and 28. Silver layer 24 makes up the balance, about 5 percent to about 25 percent, of the total thickness of the deposited metal layers. The various thicknesses will be adjusted to attain the desired proportion of tin to silver in the overall thickness of the alloy layer 32. The metal underplate layer is selected from metals whose melting point is high enough that the underplate layer is not melted during heating to melt the tin and silver layers. In one embodiment of the present invention, a copper or nickel underplate layer, a tin first layer, a second intermediate silver layer, and a third tin top layer are sequentially applied to the electrically conductive substrate in carefully controlled respective thicknesses by any suitable means. The layers may be applied, for example, by electrolytic-ion reduction, electrolysis, catalytic reduction or chemical replacement reactions. In this embodiment, the result is a solid, three-layer composite comprised of an intermediate silver layer sandwiched between two tin layers atop a copper, nickel or other suitable metal underplate layer.

Referring now to FIG. 4, there is shown a phase diagram for tin-silver as a curve plotting the temperatures in degrees Centigrade on the vertical axis and the percent by weight silver in the tin-silver alloy on the horizontal axis. The phase diagram of FIG. 4 is taken from the book Equilibrium Data For Tin Alloys, September 1949, Tin Research Institute of Greenford, Middle-sex, Great Britain. It will be seen that as the silver content of the tin-silver alloy increases, a higher temperature is required to maintain the alloy in a fully molten state. The line 44 in FIG. 4 shows the temperature required to maintain a fully molten state of the various tin-silver compositions shown as percent by weight silver on the horizontal axis of the graph. At zero silver at the left edge of the plot, line 44 is at the melting point of pure tin, 449.4° F. (231.9° C.) whereas at 100 percent silver, line 44 is at the melting point of pure silver, 1,760.9° F. (960.5° C.). Beneath line 44 are shown various phases, some of which have molten metal in equilibrium with alloy solids. By heating the three applied tin and silver layers 20, 24 and 28 to a temperature at or above line 44, the all molten or liquid phase is maintained. Although there are initially three discrete solid layers of tin, silver and tin, because of the extreme thinness of the layers, as soon as the tin layers start to soften, diffusion of the very thin tin and silver layers into each other rapidly facilitates melting and dissolution of the silver into the molten tin to form a fully dispersed tin-silver molten alloy. Because the 1,760.9° F. (960.5° C.) melting point of silver is so much higher than the 449.4° F. (231.9° C.) melting point of tin, the higher the content of silver in the reflowed tin-silver alloy the higher the melt temperature is required to be. High melt temperatures impose substantially increased heating power costs.

For example, it is seen that heating tin and silver layers of respective thicknesses which will result in an alloy containing 10 percent silver and 90 percent tin will result in a fully melted alloy at a temperature of about 300° C., which lies just at or above line 44 in the graph of FIG. 4.

### Example 1

Two samples of electrical contact material, denominated Samples J and K, were prepared as follows in accordance with embodiments of the present invention. Samples J and K were identically prepared except that an air quench was employed for Sample K, as indicated below, but not for Sample J, which was allowed to cool in ambient air.

1. For both samples, an electrically conductive substrate comprising a single 1.4″ wide×0.0118″ thick 425 copper alloy strip was run at a line speed of 5 ft/min through a plating line using the following sequences. All entries under “Chemistry” are aqueous solutions. “Amps” under “Elect. Data”, i.e., Electrical Data, means amps per square foot of electrically conductive substrate. “N/A” means not applicable.

| Seq # | Process Step | Chemistry | Elect. Data | Temp. |
|---|---|---|---|---|
| 20 | Reverse Cleaner | 8-14 oz/gal of a caustic | 3-5 volts with | 150-170° F. |
| | | surfactant. | polarity reversed | (65.6-76.7° C.) |
| | | | so that | |
| | | | the electrically | |
| | | | conductive | |
| | | | substrate | |
| | | | is positive | |
| | | | and the anode | |
| | | | is negative. | |
| 30 | Nitric Acid | 3-5 oz. HNO₃/gal | N/A | 55-95° F. |
| | Activation | | | (12.8-35° C.) |
| 40 | Sulfamate Nickel | 10-15 oz/gal metal. | 80 Amps | 120-140° F. |
| | | pH 2-4 | | (48.9-60° C.) |
| | | Boric Acid 4-6 oz/gal | | |
| 50 | Sulfuric Acid | 0.5-2% | N/A | 55-95° F. |
| | | | | (12.8-35° C.) |
| 60 | Matte Tin Sulfate | 4-6 oz/gal metal | 34 Amps | 120-135° F. |
| | | 1.5-2.5N Acid | | (48.9-57.2° C.) |
| 65 | Water Rinse | N/A | N/A | 110-130° F. |
| | | | | (43.3-54.4° C.) |
| 70 | Silver Strike | 1.0-2.0 g/l metal | 11 Amps | 75-95° F. |
| | | KCN 12-17 oz/gal | | (23.9-35° C.) |
| 74 | Water Rinse | N/A | N/A | 110-130° F. |
| | | | | (43.3-54.4° C.) |
| 76 | Matte Tin Sulfate | 4-6 oz/gal metal | 34 Amps | 120-135° F. |
| | | 1.5-2.5N Acid | | (48.9-57.2° C.) |
| 80 | Water Spray Rinse | N/A | N/A | 55-95° F. |
| | | | | (12.8-35° C.) |
| 83 | Flux Application | 20-30 ml/gal of an | N/A | 85-115° F. |
| | | acidic flux. | | (29.4-46.1° C.) |
| 87 | Reflow | N/A | N/A | 550-600° F. |
| | | | | (287.8-315.6° C.) |
| | | | | (surface temp) |
| 88 | Air Quench (Sample | N/A | N/A | 60-80° F. |
| | K only) | | | (15.6-26.7° C.) |
| 90 | Water Bath | N/A | N/A | 60-80° F. |
| | | | | (15.6-26.7° C.) |
| 95 | Water Spray Rinse | N/A | N/A | 60-80° F. |
| | | | | (15.6-26.7° C.) |
| 96 | Water Spray Rinse | N/A | N/A | 100-150° F. |
| | | | | (37.8-65.6° C.) |
| 100 | Forced Air Dry | N/A | N/A | 60-80° F. |
| | | | | (15.6-26.7° C.) |

Special process Notes:
1) Strip must remain wet between bays
2) End dam rubbers must be clean and wet to wipe liquid from strip between bays.
3) Any surface scratches will cause dewetting (after reflow)
4) Strip must be dry prior to reflow (to prevent staining)
5) Time remaining in the reflow (heating) chamber after melting of the coating must be controlled to provide an appropriate melt duration as described above. Onset of melt duration is indicated by the matte finish of the coating becoming shiny and wet-looking. Check on-set of melting by visual observation through viewing port.
6) Good rinsing is required prior to application of flux
7) Check surface temperature of strip during reflow by using infrared gun

Plating details of Samples J and K are summarized in the following TABLE I.

TABLE I
Plating Details

| | | Thickness |
|---|---|---|
| | | Microinches |
| Sample | Plating | (Microns) |
| J | Nickel Underplate Layer | 56 (1.4) |
| | Sn/Ag Alloy (Nominally, 95 wt. % Sn, 5 | 88 (2.2) |
| | wt. % Ag) | |
| K | Nickel Underplate Layer | 56 (1.4) |
| | Sn/Ag Alloy (Nominally, 95 wt. % Sn, 5 | 64 (1.6) |
| | wt. % Ag) | |

Samples J and K were sectioned and examined by Scanning Electron Micro-scope/Energy Dispersive X-Ray Spectroscopy (SEM/EDS). The SEM magnification was standardized using National Bureau of Standards SRM 1367 for 3.6 microns and was used to determine the thicknesses of the plated coatings, which are presented in TABLE I above.

### Example 2

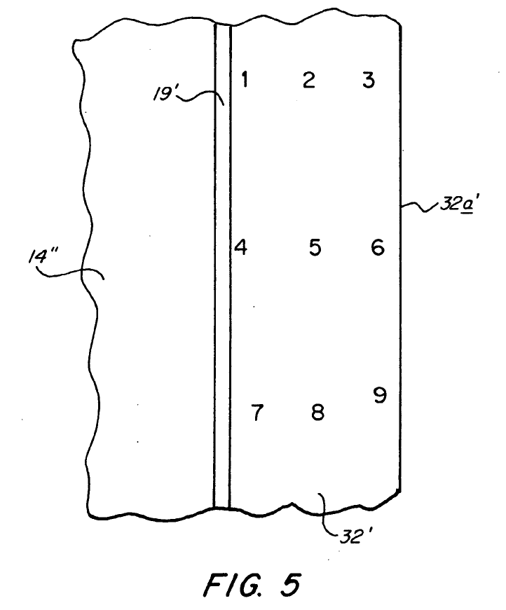

The composition of the plating was determined by SEM/EDS using the same magnification as was used to determine the thickness of the plating coatings in Example 1. The compositions were determined in the nine cross-sectional locations shown in FIG. 5, as follows. Locations 1, 4 and 7 are adjacent to the nickel underplate layer 19′ disposed on a surface of electrically conductive substrate 14″, locations 2, 5 and 8 are in about the center of the tin-silver alloy coating 32′ and locations 3, 6 and 9 are adjacent to the outer surface 32a′ of the tin-alloy coating. The results are presented in TABLE II, in which the sample identifier prefix J or K has been added to the location numbers shown in FIG. 5.

TABLE II
COMPOSITION OF SN—AG REFLOWED ALLOY

| | |
|---|---|
| Location | Weight % Ag (Remainder is Sn) |

A. Sample J - No Air Quench
1. Sample J - Adjacent the Ni Layer (“Inner”)

| | |
|---|---|
| J-1 | 3.66 |
| J-4 | 4.53 |
| J-7 | 2.97 |
| | Average: 3.72% Ag |
| | Mean: 3.75% Ag |

2. Sample J - At the Center of the Sn—Ag Alloy (“Center”)

| | |
|---|---|
| J-2 | 5.96 |
| J-5 | 6.04 |
| J-8 | 4.81 |
| | Average: 5.60% Ag |
| | Mean: 5.43% Ag |

3. Sample J - Adjacent the Outer Surface of the Sn—Ag Alloy (“Outer”)

| | |
|---|---|
| J-3 | 3.61 |
| J-6 | 5.82 |
| J-9 | 4.85 |
| | Average: 4.76% Ag |
| | Mean: 4.72% Ag |

B. Sample K - Air Quench By Forced Air Blower
4. Sample K - Adjacent the Ni Layer (“Inner”)

| | |
|---|---|
| K-1 | 3.80 |
| K-4 | 4.24 |
| K-7 | 3.44 |
| | Average: 3.83% Ag |
| | Mean: 3.84% Ag |

5. Sample K - At the Center of the Sn—Ag Alloy (“Center”)

| | |
|---|---|
| K-2 | 4.89 |
| K-5 | 5.11 |
| K-8 | 4.34 |
| | Average: 4.78% Ag |
| | Mean: 4.73% Ag |

6. Sample K - Adjacent the Outer Surface of the Sn—Ag Alloy (“Outer”)

| | |
|---|---|
| K-3 | 5.83 |
| K-6 | 5.35 |
| K-9 | 5.12 |
| | Average: 5.43% Ag |
| | Mean: 5.48% Ag |

The above results show that Sample J, which was not quenched by forced air, has a silver content which is higher at locations J-2, J-5 and J-8 (the center of the tin-silver alloy) than at the other locations. In contrast, Sample K, which was air-quenched by forced air blown into the molten outer surface, has a silver content which is higher at locations K-3, K-6 and K-9 near the outer (quenched) surface of the tin-silver alloy. These results show that more rapid cooling and solidification of the outer surface of the tin-silver alloy causes increased migration of silver to the outer surface, thereby enhancing electrical conductivity and reducing friction at the outer (contact) surface of the tin-silver alloy. The results also show that there is no residual silver layer, that is, the silver in the pre-reflow silver layer has been dispersed throughout the tin-silver alloy, as has the tin.

Generally, upon re-solidification, the portion of the tin-silver coating which re-solidifies (“freezes”) first has a higher concentration of silver than that portion of the tin-silver coating which re-solidifies at a later time. For this reason, as shown by Sample K, quenching or accelerated cooling may be utilized to provide a somewhat higher concentration of silver at and near the cooled surface of the coating. This is advantageous in that it provides the surface with enhanced electrical conductivity and reduced coefficient of friction. Although a desirable silver concentration gradient is produced or enhanced by differential cooling (quenching), no discrete silver layer remains in the reflowed, fully dispersed tin-silver alloy.

Generally, for purposes of electrical contact materials, at least 5 weight % silver is desirable because amounts of silver significantly less than 5 weight %, e.g., 4 weight % to 4.5 weight % or less, in the tin-silver alloy provides but little enhancement in conductivity and reduced friction as compared to a pure (unalloyed) tin coating. On the other hand, quantities of silver in excess of 40% require power input for melting which may be economically unfeasible. Accordingly, the preferred silver content is from about 5% to about 40% by weight silver and more preferably the quantity of silver in the alloy is from about 5% to about 20% silver, most preferably from about 5% to 10% by weight silver.

Generally, the reflow melt surface temperatures are in the range of about 220° C. to about 410° C., e.g., from about 221° C. or about 225° C. or any temperature therebetween, to about 410° C. or even higher.

While the invention has been described in detail with respect to a specific embodiment thereof, it will be appreciated that the invention has other applications and may be embodied in numerous variations of the illustrated embodiments.

What is claimed is:

1. A method of manufacturing an electrically conductive substrate having a tin-silver alloy coated on at least one surface of the substrate with the tin-silver alloy having an outer surface, the method comprising:
applying to the surface of the electrically conductive substrate a surface coating comprising a tin prime coat, an intermediate silver coat over the tin prime coat, and a tin top coat over the intermediate silver coat;
heating the coated electrically conductive substrate to an elevated temperature of at least about 220° C., which temperature is sufficiently high to melt the entirety of the coating, and maintaining the coated substrate at the elevated temperature for at least a time sufficient to melt the entire coating and fully disperse the silver therein (“the melt duration”); and
thereafter cooling the coating to re-solidify it and thereby provide a solid, reflowed tin-silver alloy coating on the electrically conductive substrate.

2. A method of manufacturing electrical contact material comprises:
a) applying to at least one surface of an electrically conductive substrate; at least the one surface of which comprises copper, a reflowed tin-silver alloy coating having an outer surface and comprising from about 5 to about 40 weight percent silver by:
(i) applying to the surface of the electrically conductive substrate a tin prime coat;
(ii) applying an intermediate silver coat over the tin prime coat;
(iii) applying a tin top coat over the silver intermediate coat;
b) then heating the thus-coated electrically conductive substrate to an elevated temperature of at least about 220° C. and sufficiently high to melt the applied tin and silver layers, and maintaining the coated electrically conductive substrate at the elevated temperature for at least a time sufficient to melt all the tin and silver layers and fully disperse the silver therein (the “melt duration”); and
thereafter cooling the coated electrically conductive substrate to re-solidify the melted tin and silver to thereby provide a reflowed tin-silver alloy on the substrate.

3. The method of claim 1 or claim 2 wherein the intermediate silver coat is thinner than either of the tin prime coat and the tin top coat.

4. The method of claim 3 wherein the intermediate silver coat is thin enough whereby the entirety of the intermediate silver coat will melt and disperse into the tin coats when the coating is subjected to a temperature of from about 220° C. to about 410° C. for a melt duration of from about 0.05 to about 5 seconds.

5. The method of claim 1 or claim 2 wherein the intermediate silver coat is from about 4 to about 12 microinches in thickness.

6. The method of claim 1 or claim 2 wherein the elevated temperature is from about 220° C. to about 410° C.

7. The method of claim 1 or claim 2 further including applying a metal underplate layer to the surface before applying the tin prime coat of the coating.

8. The method of claim 7 wherein the metal underplate layer is selected from the group consisting of one or more of copper and nickel.

9. The method of claim 7 wherein the metal underplate layer comprises nickel.

10. The method of claim 1 or claim 2 wherein the reflowed tin-silver alloy comprises from about 5 to about 40 weight percent silver.

11. The method of claim 1 or claim 2 wherein at least the surface of the electrically conductive substrate comprises copper.

12. The method of claim 1 or claim 2 wherein the tin-silver alloy coated on the electrically conductive substrate is from about 40 to about 120 microinches in thickness.

13. The method of claim 12 wherein the elevated temperature is from about 220° C. to about 410° C.

14. The method of claim 1 or claim 2 wherein the tin and silver coats are all applied to the electrically conductive substrate by electrolytic plating from separate tin and silver plating baths.

15. The method of claim 14 wherein the underplate layer is applied to the electrically conductive substrate by electrolytic plating from a metal plating bath which is separate from the separate tin and silver plating baths.

16. The method of claim 1 or claim 2 wherein the melt duration is from about 0.05 to about 5 seconds.

17. The method of claim 16 wherein the elevated temperature is from about 220° C. to about 410° C.

18. The method of claim 1 or claim 2 wherein the solidification step is carried out by forced air applied to the outer surface of the tin-silver coating.

19. The method of claim 1 or claim 2 further comprising applying to the coating additional alternating tin and silver coats with each silver coat sandwiched between two tin coats.

20. A coated metal electrically conductive substrate having thereon a tin-silver alloy coating having an outer surface, and wherein the silver is fully dispersed within the tin-silver alloy coating and there is a silver concentration gradient extending through the thickness of the coating from the electrically conductive substrate to the outer surface of the tin-silver alloy coating.

21. The coated metal electrically conductive substrate of claim 20 made by the method of any one of claim 1 or claim 2.

22. The coated electrically conductive substrate of claim 21 wherein at least the coated surface of the substrate comprises copper.

23. The coated metal electrically conductive substrate of claim 20 wherein the silver concentration gradient increases at least adjacent to the outer surface of the tin-silver alloy coating in the direction from the substrate to the outer surface of the tin-silver alloy coating.

24. A coated metal electrically conductive substrate having thereon a tin-silver alloy coating having an outer surface, and wherein the silver is fully dispersed within the tin-silver alloy coating and there is a silver concentration gradient extending through at least a portion of the thickness of the coating and increasing towards the outer surface of the tin-silver alloy coating, the coated substrate being made by the method of either claim 1 or claim 2.

25. The coated metal electrically conductive substrate of claim 20 or claim 23 wherein at least the coated surface of the electrically conductive substrate comprises copper.

26. The coated electrically conductive substrate of claim 20 or claim 23 configured to comprise an electrical contact device.
